(19) United States
(12) Patent Application Publication
(10) Pub. No.: US 2025/0166972 A1
(43) Pub. Date: May 22, 2025

(54) METHOD AND SYSTEM FOR PLASMA PROCESS

(71) Applicant: Tokyo Electron Limited, Tokyo (JP)

(72) Inventors: Evrim Solmaz, Austin, TX (US); Du Zhang, Albany, NY (US); Barton Lane, Austin, TX (US)

(21) Appl. No.: 18/517,206

(22) Filed: Nov. 22, 2023

(51) Int. Cl. H01J 37/32

(52) U.S. Cl. CPC H01J 37/32366; H01J 37/3244; H01J 2237/327; H01J 2237/334

(57) ABSTRACT

An example method for a plasma process includes generating plasma within a process chamber with source power (SP) pulses. The source power pulses have a repetition frequency. The method further includes adjusting a neutral flux within the process chamber by changing the repetition frequency of the source power pulses. In some embodiments, the plasma etches a substrate.

### TECHNICAL FIELD

The present invention relates generally to plasma processing, and, in particular embodiments, to plasma processing methods, apparatuses, and systems.

### BACKGROUND

Device formation within microelectronic workpieces can involve a series of manufacturing techniques including formation, patterning, and removal of a number of layers of material on a substrate. In order to achieve the physical and electrical specifications of current and next generation semiconductor devices, processing flows enabling reduction of feature size while maintaining structural integrity is desirable for various patterning processes. As device structures densify and develop vertically, the desire for precision material processing becomes more compelling.

Plasma processes are commonly used to form devices, interconnects, and contacts in microelectronic workpieces. For example, plasma etching and plasma deposition are common process steps during semiconductor device fabrication. A combination of source power (SP) applied to a coupling element and bias power (BP) applied to a substrate holder can be used to generate and direct plasma. Various conditions during a plasma process may influence whether material is being deposited onto a substrate, etched from the substrate, or a combination of the two.

### SUMMARY

In accordance with an embodiment, a method for a plasma process includes: generating plasma within a process chamber with source power (SP) pulses, the SP pulses having a repetition frequency; and adjusting a neutral flux within the process chamber by changing the repetition frequency of the SP pulses.

In accordance with another embodiment, a method for an etch process includes: starting a pulsed plasma process with source power (SP) pulses, the SP pulses having a repetition frequency, the pulsed plasma process generating a plasma; etching a substrate with the plasma; and while etching the substrate, continuously changing the repetition frequency of the SP pulses.

In accordance with yet another embodiment, a method for processing a substrate includes: providing a substrate onto a substrate holder in a process chamber; etching an opening into the substrate with a pulsed plasma process, the pulsed plasma process including: generating a plasma with source power pulses, the plasma including carbon, fluorine, oxygen, nitrogen, hydrogen, or argon; and while generating the plasma, ramping down a repetition frequency of the source power pulses; and filling the opening with a conductive material.

It is to be understood that both the foregoing general description and the following detailed description are exemplary and explanatory only and are not restrictive of the disclosure, as claimed.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example plasma processing system, in accordance with some embodiments;

FIG. 2 illustrates graphs of source power pulses and neutral radical flux versus time, in accordance with some embodiments;

FIG. 3A illustrates a cross-sectional view of a semiconductor structure during an intermediate stage of manufacturing, in accordance with some embodiments;

FIG. 3B illustrates a cross-sectional view of a semiconductor structure during an intermediate stage of manufacturing, in accordance with some embodiments;

FIG. 3C illustrates a cross-sectional view of a semiconductor structure during an intermediate stage of manufacturing, in accordance with some embodiments;

FIG. 3D illustrates a cross-sectional view of a semiconductor structure during an intermediate stage of manufacturing, in accordance with some embodiments;

FIGS. 4A and 4B illustrate graphs of number density of neutral radicals and electrons versus source power pulse repetition frequency, in accordance with some embodiments;

FIGS. 5 and 6 illustrate tables of time-averaged number densities for various species, in accordance with some embodiments;

FIG. 7 illustrates a process flow chart diagram of a method for a plasma process, in accordance with some embodiments;

FIG. 8 illustrates a process flow chart diagram of a method for an etch process, in accordance with some embodiments; and

FIG. 9 illustrates a process flow chart diagram of a method for processing a substrate, in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Both source power (SP) and bias power (BP) may be supplied as radio frequency (RF) power to the processing chamber of a plasma processing apparatus. Pulsed plasma processing methods supply one or both of the RF source power and RF bias power to a processing chamber as pulses rather than as continuous wave power. For example, BP pulses may be provided synchronously or asynchronously with SP pulses. Such existing synchronous/asynchronous schemes often use a single RF frequency for the bias power, even when supplying the bias power asynchronously (e.g., single frequency, dual-phase), and may not be adequate to independently control etching and deposition.

Some conventional methods mix RF frequencies to shape the waveform of the BP pulses, but such methods are employed to influence plasma uniformity and do not afford independent control over deposition and etching.

Other conventional methods supply BP pulses with high RF frequency and high power along with the SP pulses and low RF frequency, low power BP pulses with very short duration in between SP pulses to avoid plasma generation and heating. However, the high RF frequency BP pulses may not allow fine control over deposition while the source power is due to generation of high-energy ions with significant verticality. Meanwhile, the low RF frequency BP pulses are intended to reduce any disruption to the plasma structure and therefore may lack the flexibility necessary for full control over etching.

Etching during plasma processes may be driven by synergy between interaction of a substrate surface with neutral radicals and with ions. For example, neutral radicals (also referred to as neutral species or neutrals) are adsorbed by the surface while ions bombard the surface and cause desorption of substrate particles. This desorption of substrate particles drives the etching process. For non-self-limiting neutral adsorption (such as occurs with polymerizing gas), a too high neutral flux may decrease the etch rate of the plasma process or may induce undesirable feature clogging (such as of high aspect ratio holes or trenches) by thicker deposition. Using a constant source power pulse frequency throughout an etch process may restrict the ability to change neutral radical fluxes due to evolving of the etch profile of the target surface. Therefore, it is desirable to adjust the neutral flux as the profile of the target surface evolves during the etch process. This may achieve neutral flux modulation and control the time-averaged ion/neutral chemical balance.

Changing the source power (SP) pulse frequency in a transient etch process can achieve desirable adjustment of the time-averaged neutral flux. The source power pulse frequency may be changed gradually to prevent discontinuities from being formed in the etch profile. The pulse-period-averaged (PPA) neutral radical flux Γrad changes when the source power pulse repetition frequency (PRF) is changed. For example, in the case of a plasma formed from a precursor gas comprising an admixture of tetrafluoromethane and oxygen (CF₄/O₂), the neutral radical flux Γrad and the source power pulse repetition frequency are proportional to each other. This relationship can be used to control the balance of ion flux and neutral radical flux with a gradual ramping of the source power pulse repetition frequency.

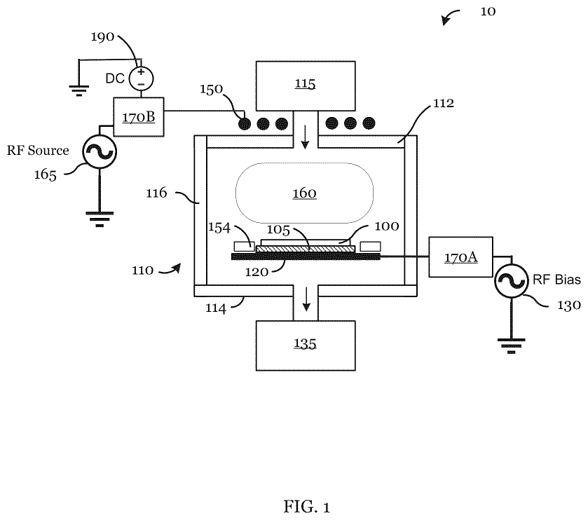

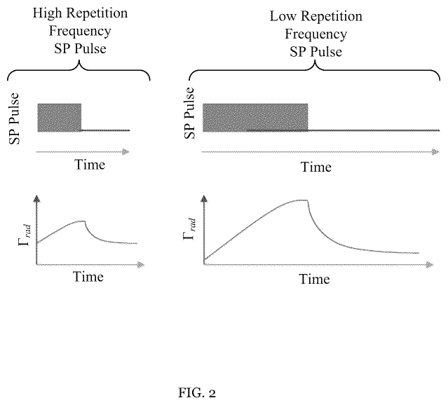

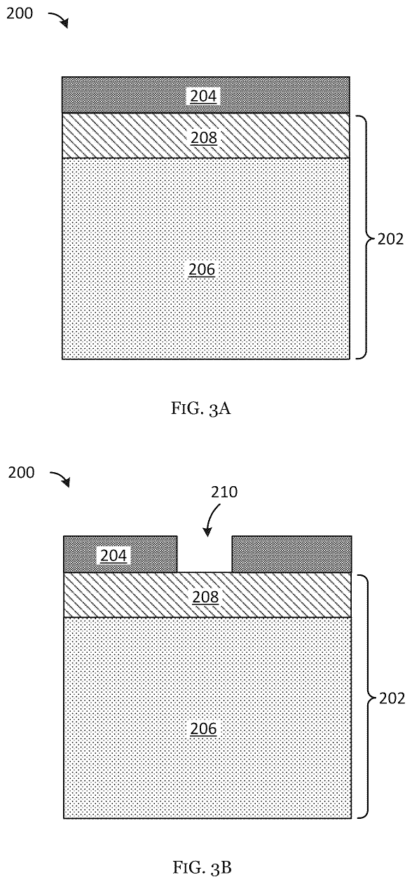

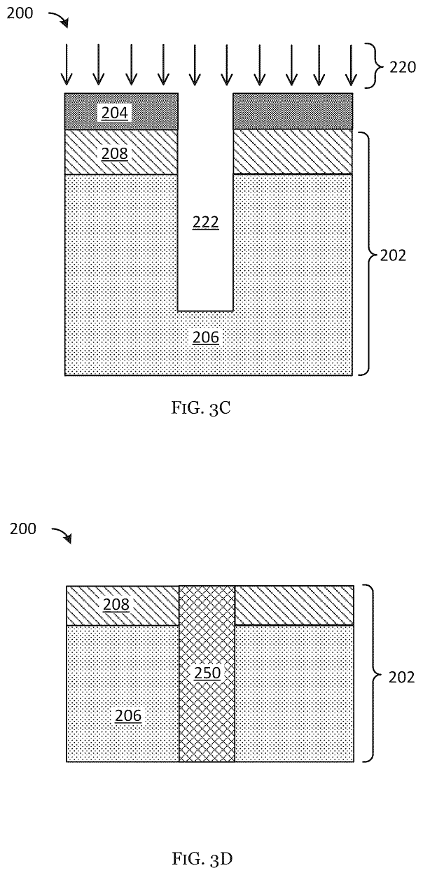

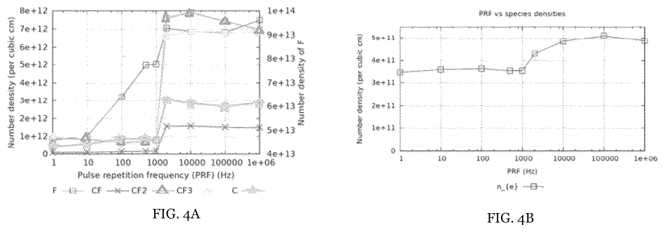

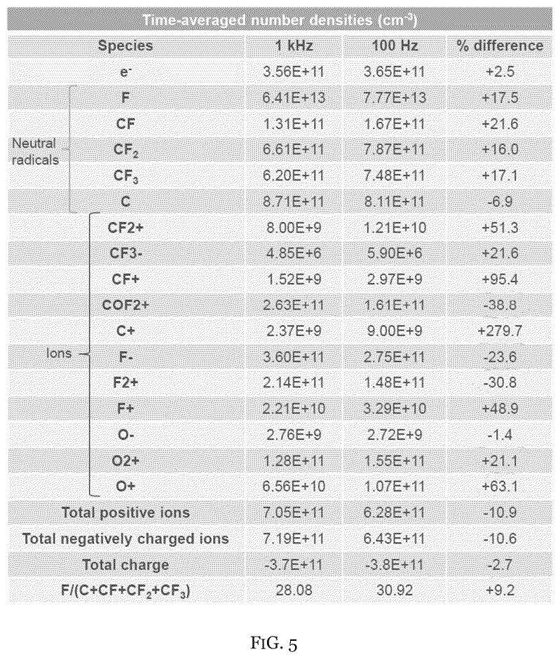

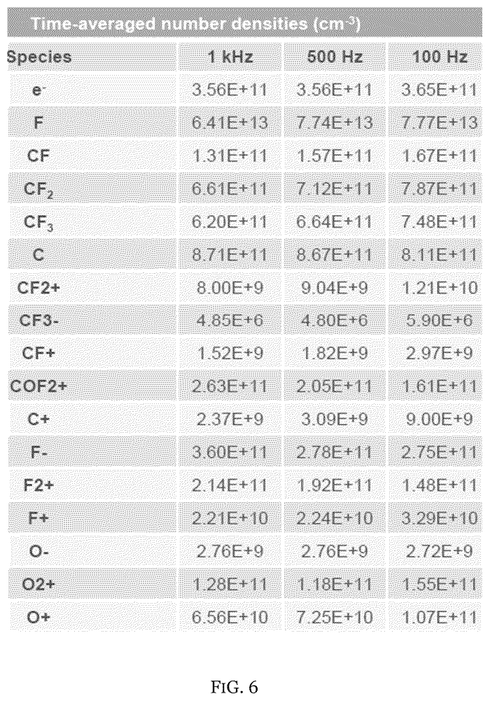

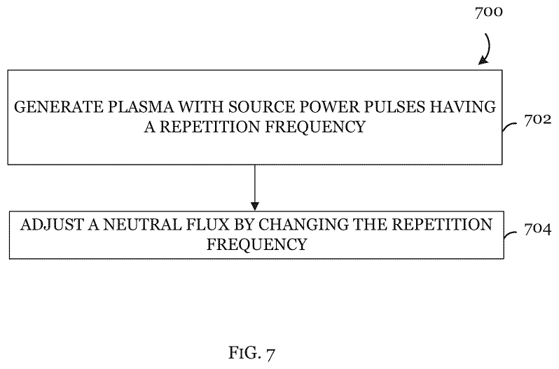

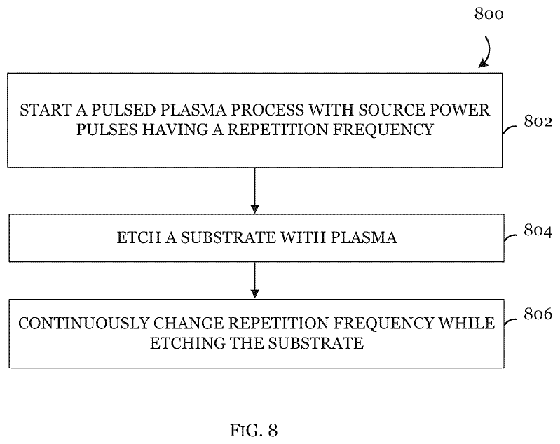

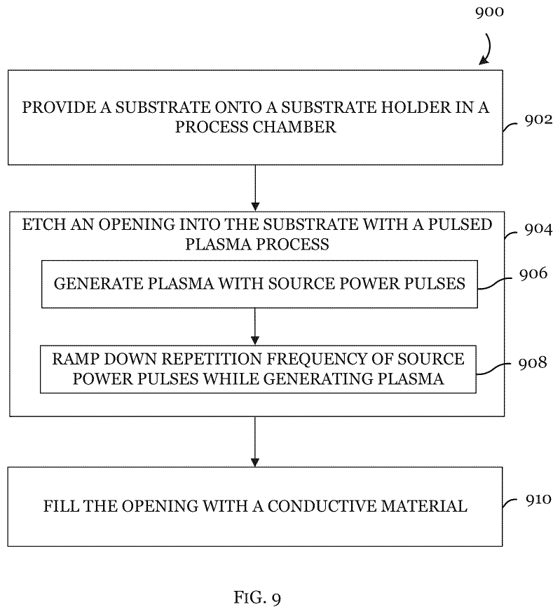

Embodiments of the disclosure are described in the context of the accompanying drawings. An embodiment of an example plasma processing system will be described using FIG. 1. An embodiment of changing source power pulse repetition frequency will be described using FIG. 2. An embodiment of a method for processing a substrate will be described using FIGS. 3A-3D. Simulation results of number density of neutral radicals and electrons versus source power pulse repetition frequency will be described using FIGS. 4A and 4B. Simulation results of time-averaged number densities for various species will be described using FIGS. 5 and 6. An embodiment of a method for a plasma process will be described using FIG. 7. An embodiment of a method for an etch process will be described using FIG. 8. An embodiment of another method for processing a substrate will be described using FIG. 9.

FIG. 1 illustrates an example plasma processing system 10, in accordance with various embodiments. As illustrated in FIG. 1, the plasma processing system 10 comprises a plasma processing chamber 110 with source power excitation and substrate bias power (in other words, wafer biasing capabilities). A substrate 100 may be placed on a substrate holder 105. In various embodiments, the substrate 100 may be a part of, or including, a semiconductor device, and may have undergone a number of steps of processing following, for example, a conventional process. The substrate 100 accordingly may comprise layers of semiconductors useful in various microelectronics. For example, the semiconductor structure may comprise the substrate 100 in which various device regions are formed.

In one or more embodiments, the substrate 100 may be a silicon wafer, or a silicon-on-insulator (SOI) wafer. In certain embodiments, the substrate 100 may comprise a silicon germanium wafer, silicon carbide wafer, gallium arsenide wafer, gallium nitride wafer and other compound semiconductors. In other embodiments, the substrate 100 comprises heterogeneous layers such as silicon germanium on silicon, gallium nitride on silicon, silicon carbon on silicon, as well layers of silicon on a silicon or SOI substrate. In various embodiments, the substrate 100 is patterned or embedded in other components of the semiconductor device.

In various embodiments, the plasma processing system 10 may further comprise a focus ring 154 positioned over the bottom electrode 120 to surround the substrate 100. The focus ring 154 may advantageously maintain and extend the uniformity of a plasma 160 to achieve process consistency at the edge of the substrate 100. In various embodiments, the focus ring 154 may have a width of a few cm. In various embodiments, there may be a gap for mechanical clearance between the circumference of the substrate 100 and the focus ring 154. In certain embodiments, the gap may be hundreds of microns to a few mm. In various embodiments, the focus ring 154 may comprise a dielectric material with a desired dielectric constant. In certain embodiments, the focus ring 154 may comprise silicon. Some examples of silicon-based focus ring may comprise silicon, silicon oxide, doped silicon (e.g., boron-doped, nitrogen-doped, and phosphorous-doped), or silicon carbide. Alternatively, in some embodiments, the focus ring may comprise a carbon-based material. In one or more embodiments, the focus ring 154 may comprise a metal oxide, such as aluminum oxide and zirconium oxide.

A process gas may be introduced into the plasma processing chamber 110 by a gas delivery system 115. The gas delivery system 115 may comprise multiple gas flow controllers to control the flow of multiple gases into the plasma processing chamber 110. Any precursors that can create a plasma may be used, such as argon (Ar), tetrafluoromethane (CF₄), oxygen (O₂), an admixture of tetrafluoromethane and oxygen (CF₄/O₂), hexafluorobutadiene (C₄F₆), octafluorocyclobutane (C₄F₈), nitrogen (N₂), hydrogen (H₂), hydrogen bromide (HBr), the like, or any combination, or admixture thereof in any suitable ratio. In some embodiments, optional center/edge splitters may be used to independently adjust the gas flow rates at the center and edge of the substrate 100. In various embodiments, the total flow rate of the gas is in a range of 1 standard cubic centimeters per minute (sccm) to 5000 sccm, at a pressure in a range of 0.1 mTorr to 1 Torr, and/or at a temperature in a range of −200° C. to 500° C.

Further, in one embodiment, the gas delivery system 115 may have a special showerhead configuration positioned at the top of the plasma processing chamber 110. For example, the gas delivery system 115 may have a showerhead configuration, covering the entirety of the substrate 100, including a plurality of appropriately spaced gas inlets. Alternatively, gas may be introduced through dedicated gas inlets of any other suitable configuration. The plasma processing chamber 110 may further be equipped with one or more sensors such as pressure monitors, gas flow monitors, and/or gas species density monitors. The sensors may be integrated as a part of the gas delivery system 115 in various embodiments.

In FIG. 1, the plasma processing chamber 110 is a vacuum chamber and may be evacuated using one or more vacuum pumps 135, such as a single stage pumping system or a multistage pumping system (e.g. a mechanical roughing pump combined with one or more turbomolecular pumps). In order to promote even gas flow during plasma processing, gas may be removed from more than one gas outlet or location in the plasma processing chamber 110 (e.g., on opposite sides of the substrate 100).

In various embodiments, the substrate holder 105 may be integrated with, or a part of, a chuck (e.g., a circular electrostatic chuck (ESC)) positioned near the bottom of the plasma processing chamber 110, and connected to a bottom electrode 120. The surface of the chuck or the substrate holder 105 may be coated with a conductive material (e.g., a carbon-based or metal-nitride based coating). The substrate 100 may be optionally maintained at a desired temperature using a temperature sensor and a heating element connected to a temperature controller (not shown). In certain embodiments, the temperature sensor may comprise a thermocouple, a resistance temperature detector (RTD), a thermistor, or a semiconductor based integrated circuit. The heating element may for example comprise a resistive heater in one embodiment. In addition, there may be a cooling element such as a liquid cooling system coupled to the temperature controller. The bottom electrode 120 may be coupled to a RF bias power source 130, such as through or controlled by a controller 170A.

Further in FIG. 1, a top electrode 150 may be a conductive helical coil electrode located outside the plasma processing chamber 110, positioned above a top plate 112. The top electrode 150 may be coupled to RF power source 165 via a controller 170B. The top plate 112, a bottom plate 114, and a side wall 116 may be conductive and electrically connected to the system ground (a reference potential).

In some embodiments, the controller 170A and the controller 170B are coupled together or are part of a single controller, such as a programmable processor, microprocessor, computer, or the like. Although the controllers 170A and 170B is illustrated as two element for illustrative purposes, the controllers 170A and 170B may include additional elements or be part of a single element. The controllers 170A and 170B may be programmable by instructions stored in software, firmware, hardware, or a combination thereof. The controllers 170A and 170B may be configured to set, monitor, and/or control various control parameters associated with generating a plasma and delivering ions to the surface of a microelectronic workpiece. Control parameters may include, but are not limited to, power level, frequency, and duty cycle (%) for both the source power and the bias power as well as delay time between source power pulse and bias power pulse. Other control parameter sets may also be used.

In some embodiments, the operating pulse frequency range for the RF source power is 1 Hz to 10 MHz. While only one RF power source is illustrated in FIG. 1, more than one RF power source(s) may be used in various embodiments, for example, to provide a low frequency RF power and a high frequency RF power at the same time. The plasma 160 may be generated and sustained by pulsed RF power.

In various embodiments, a RF pulsing at a kHz range may be used to power the plasma 160. Using the RF pulsing may help generating high energetic ions (>keV) in the plasma 160 for the plasma etch process, while reducing a charging effect.

In some embodiments, the operating frequency range for the RF bias power is 100 kHz to 10 GHz. While only one bias RF power source is illustrated in FIG. 1, more than one bias RF power source(s) may be used in various embodiments, for example, to provide a low frequency bias RF power and a high frequency bias RF power at the same time and enable changing the bias RF frequency more rapidly.

The configurations of the plasma etching system described above is for example only. In alternative embodiments, various alternative configurations may be used for a plasma processing system that incorporates a set of electromagnets. For example, the plasma processing system may be a resonator such as a helical resonator that produces helicons. Further, microwave plasma (MW), electron cyclotron resonance (ECR), capacitively coupled plasma (CCP), multi-frequency CCP, inductively coupled plasma (ICP), or other suitable systems may be used. In various embodiments, the RF power, chamber pressure, substrate temperature, gas flow rates and other plasma process parameters may be selected in accordance with the respective process recipe.

In addition, embodiments of the present invention may be also applied to remote plasma systems as well as batch systems. For example, the substrate holder may be able to support a plurality of wafers that are spun around a central axis as they pass through different plasma zones. Accordingly, it is possible to have multiple plasma zones, for example, including a metal-containing plasma zone, metal-free plasma zone, and plasma-free zone (e.g., a purge zone). Example embodiments of the disclosure are summarized here. Other embodiments can also be understood from the entirety of the specification as well as the claims filed herein.

FIG. 2 illustrates graphs of source power pulses and neutral radical flux versus time for high repetition pulse frequency and low repetition pulse frequency, in accordance with some embodiments. Repetition pulse frequency, in an embodiment, may be the frequency at which the pulses repeat. If the pulse repetition frequency is continuously changing (in other words, ramping up or down), the pulses have an instantaneous frequency that is the frequency at which the pulses would be repeating if the ramping stopped at that moment. In other words, the inverse of the time period between each pulse may provide the instantaneous frequency and therefore the repetition frequency. Neutral radical flux may accompany ion flux in a plasma process, such as may be performed in an example plasma processing system 10 using pulsed source power and bias power (see above, FIG. 1). As illustrated by FIG. 2, the neutral radical flux Γ_{rad} and the source power pulse repetition frequency may be proportional to each other, such as in the case of a plasma formed from a precursor gas comprising an admixture of tetrafluoromethane and oxygen (CF₄/O₂). The left column of FIG. 2 illustrates a source power pulse and a respective neutral radical flux for a source power pulse with a high repetition frequency, and the right column of FIG. 2 illustrates a source power pulse and a respective neutral radical flux for a source power pulse with a low repetition frequency. The source power pulse of the left column is shorter in time than the source power pulse of the right column due to its relatively higher repetition frequency.

As illustrated in FIG. 2, more modulation occurs for the pulse-period-averaged neutral radical flux Γ_{rad} for a source power pulse with a relatively lower repetition frequency. In general, the neutral radical flux Γ_{rad} increases as the repetition frequency of the source power pulse increases. This may happen because decay timescales in the afterglow phase (in other words, after or between source power pulses) are slower than rise timescales in the active glow phase (in other words, during the source power pulses). This relationship may be useful for controlling the balance of ion flux and neutral radical flux with a gradual ramping of the source power pulse repetition frequency, such as while the profile of the target surface evolves during the etch process. This may be advantageous for achieving neutral flux modulation and controlling the time-averaged ion/neutral chemical balance while reducing or preventing the formation of discontinuities in the etch profile. This process may be beneficial for forming high aspect ratio openings in substrates.

FIGS. 3A-3D illustrate an example process for processing a substrate, in accordance with some embodiments. FIGS. 3A-3C illustrate cross sectional views of a semiconductor structure 200 illustrating the formation of a high aspect ratio opening in a substrate 202, and FIG. 3D illustrates the formation of a conductive feature in the high aspect ratio opening. High aspect ratio openings (e.g., openings with aspect ratios greater than 10:1, such as greater than 20:1 or greater than 50:1) can be trenches or holes with rectangular, square, circular (as in contacts) or any other regular or irregular shapes.

In some embodiments, the substrate 202 comprises a semiconductor substrate 206 such as a semiconductor wafer with an overlying dielectric layer 208. In some embodiments, the semiconductor substrate 206 is a silicon wafer, or a silicon-on-insulator (SOI) wafer. In certain embodiments, the semiconductor substrate 206 comprises a silicon germanium wafer, silicon carbide wafer, gallium arsenide wafer, gallium nitride wafer and other compound semiconductors. In other embodiments, the semiconductor substrate 206 comprises heterogeneous layers such as silicon germanium on silicon, gallium nitride on silicon, silicon carbon on silicon, as well layers of silicon on a silicon or SOI substrate. In an embodiment, the semiconductor substrate 206 is a single crystal semiconductor substrate such as a single crystal silicon wafer or a silicon-on-insulator substrate.

In various embodiments, the semiconductor structure 200 is patterned or embedded in other components of a semiconductor device. In various embodiments, the substrate 202 may be a part of a semiconductor device, and may have undergone a number of steps of processing following, for example, a conventional process. The substrate 202 accordingly may comprise layers of semiconductors useful in various microelectronics. For example, the semiconductor structure 200 may comprise a dielectric layer 208 (also referred to as a back end of line (BEOL) layer) in which various device regions are formed. The dielectric layer 208 may comprise silicon oxide, silicon dioxide, the like, or a combination thereof.

A photomask layer 204 is deposited on the substrate 202. In some embodiments, the photomask layer 204 is a trilayer photomask with a bottom organic (ODL) layer, a middle antireflective coat layer, and a top photoresist layer. However, any suitable photomask may be used for the photomask layer 204.

In FIG. 3B, a first opening 210 is formed in the photomask layer 204 using conventional photolithography techniques. As an example, the photomask layer 204 is exposed to a light pattern, such as an ultraviolet (UV), a far ultraviolet (FUV), or an extreme ultraviolet (EUV) exposure. A photomask may be used to create a light pattern by placing the photomask between the substrate 202 and a light source (not illustrated). In response to the exposure to the light pattern, a photoreaction may occur in exposed regions of the photomask layer 204, while unexposed regions remain unchanged. As a result of the photoreaction, the exposed regions may comprise a cross-linked photoresist film, which may have material properties substantially different from the unreacted portion of the photomask layer 204. Such a difference in the material properties includes volatility, reactivity, and/or solubility among others, which gives origin to the tonality as a photoresist.

Next, after exposure to the light pattern, a development process is performed on the substrate 202 with a reactive precursor. In some embodiments, the development process is a plasma-less process performed with a gaseous (non-ionized) reactive precursor (also referred to as a developing gas). The reactive precursor reacts with, e.g., the unexposed regions of the photomask layer 204 to produce volatile by-products, which then evaporate from the surface of the substrate 202 to form a first opening 210. This reaction develops the photomask layer 204. In some embodiments, the reactive precursor is a reactive gas such as hydrogen bromide (HBr), hydrogen chloride (HCl), boron trichloride (BCl₃), organic acids such carboxylic acids, methanol, ethanol, isopropyl alcohol, the like, or a mixture or combination thereof.

Next, in FIG. 3C, the first opening 210 is etched through the dielectric layer 208 with a plasma process 220 to form a high aspect ratio (HAR) second opening 222, in accordance with some embodiments. The plasma process 220 may be performed in an example plasma processing system 10 as described above with respect to FIG. 1. For example, the semiconductor structure 200 may be provided into the example plasma processing system 10 and being placed on the substrate holder 105 (such as in the place of the substrate 100; see above, FIG. 1).

The plasma process 220 may include a source phase with a source power pulse and a bias phase with a bias power pulse. In some embodiments, the bias power pulse follows the source power pulse and the source power pulse and bias power pulse do not overlap. In other embodiments, the source power pulse and bias power pulse overlap. The repetition frequency of the source power pulse may be ramped up or down during the plasma process 220, as described above with respect to FIG. 2. In some embodiments, the repetition frequency of the source power pulse is decreased from a frequency of 2 kHz or greater to a frequency of 1 kHz or less over a time period in a duration of 10 us to 1 second. In other embodiments, the repetition frequency of the source power pulse is increased from a frequency of 1 kHz or less to a frequency of 2 kHz or greater over a time period in a duration of 10 us to 1 second. The repetition frequency of the source power pulse may be increased or decreased monotonically.

In some embodiments, the plasma process 220 etches the high aspect ratio second opening 222 into the semiconductor substrate 206, such as to a depth in a range of 10 μm to 100 μm. In other embodiments, the high aspect ratio second opening 222 stops on the semiconductor substrate 206. The high aspect ratio second opening 222 can be rectangular, square, circular (as in contacts) or any other regular or irregular shape and may be formed like a trench or hole in various embodiments. In some embodiments, the plasma process 220 is performed for a duration in a range of 1 minute to 100 minutes.

In FIG. 3D, a conductive feature 250 is formed in the high aspect ratio (HAR) second opening 222 (see above, FIG. 3C). In various embodiments, the conductive feature 250 is a high aspect ratio feature (e.g., a through substrate via (TSV)). The conductive feature 250 may be formed to physically and electrically couple with conductive portions of the substrate 202, such as conductive features in the dielectric layer 208. As an example of forming the conductive feature 250, a conformal barrier metal (e.g., TiN or TaN) liner is formed over the exposed surfaces of the dielectric layer 208 and the semiconductor substrate 206. Next, the high aspect ratio second opening 222 is filled with a conductive material such as a metal. For example, the conductive material may be copper formed using electroplating. However, any suitable conductive material and deposition method may be used. Excess conductive material is then removed from the top surface of the dielectric layer 208 using a planarization process (e.g., a CMP), thereby forming the conductive feature 250 inlaid in the substrate 202.

In some embodiments, after forming the conductive feature 250, a bottom surface of the semiconductor substrate 206 is recessed to expose a respective bottom surface of the conductive feature 250. For example, the semiconductor structure 200 may be flipped over and placed on a carrier. The semiconductor substrate 206 is then recessed to expose the conductive feature 250 with a suitable process, such as a wafer backgrinding. However, any suitable method may be used to expose a respective bottom surface of the conductive feature 250.

Although FIGS. 3A-3D illustrate the formation of a single high aspect ratio second opening 222 with a plasma process 220 and a single conductive feature 250 being formed in the high aspect ratio second opening 222, it should be understood that this is disclosed as a non-limiting example. Any suitable number of high aspect ratio second openings 222 may be formed with one or more plasma processes 220 and be filled with respective conductive features 250, and all such methods and structures are within the scope of the disclosed embodiments.

FIGS. 4A and 4B illustrate graphs of simulation results for number density of neutral radicals and electrons versus source power pulse repetition frequency for a plasma formed with a precursor comprising CF₄ and O₂, in accordance with some embodiments. FIG. 4A illustrates the number densities of the individual neutral radical species F, CF, CF₂, CF₃, and C versus source power pulse repetition frequency, and FIG. 4B illustrates the total number density of electrons versus source power pulse repetition frequency. As illustrated by FIGS. 4A and 4B, the increasing trend of the number densities with increasing source power pulse repetition frequency is nearly monotonic. Additionally, the number densities show a sharp, kinetically dominant increase between 1 kHz and 2 kHz of the source power pulse repetition frequency. FIG. 4A further illustrates the F/C neutral flux ratio changing as source power pulse repetition frequency increases, which may produce a chemistry change from lean (etching) to polymerizing (depositing). As such, both the ion/neutral flux ratio and the F/C neutral flux ratios may be tuned by changing the pulse repetition frequency. The ion/neutral flux ratio change may be seen in the table of FIG. 5.

FIGS. 5 and 6 illustrate tables of simulation results for time-averaged number densities for various species including electrons, neutral radicals, and ions, in accordance with some embodiments. FIG. 5 illustrates the time-averaged number densities for various species at source power pulse repetition frequencies of 1 kHz, 100 Hz, and the percent difference between 1 kHz and 100 Hz, and FIG. 6 illustrates the time-averaged number densities for various species at source power pulse repetition frequencies of 1 kHz, 500 Hz, and 100 Hz. As illustrated by FIGS. 5 and 6, the total charge in the plasma remains largely constant with change in pulse repetition frequency, but individual ion densities and their corresponding fluxes do not remain constant. This may suggest that although the neutral and ion fluxes cannot be monitored independently, the method of changing the pulse repetition frequency may allow for tuning of the ion/neutral flux ratio as the neutral/ion chemical balance changes when the pulse repetition frequency is changed. The direction of change of the ion/neutral flux ratio with respect to the change of the pulse repetition frequency may be different for different plasmas. As such, it may be beneficial to ramp up or ramp down the pulse repetition frequency depending on the composition of the plasma being used.

FIG. 7 illustrates a process flow chart diagram of a method 700 for a plasma process, in accordance with some embodiments. In step 702, a plasma is generated within a process chamber with source power (SP) pulses, as described above with respect to FIGS. 1 and 3C. The SP pulses have a repetition frequency. In step 704 a neutral flux within the process chamber is adjusted by changing the repetition frequency of the SP pulses, as described above with respect to FIGS. 2 and 3C.

FIG. 8 illustrates a process flow chart diagram of a method 800 for an etch process, in accordance with some embodiments. In step 802, a pulsed plasma process is started with source power (SP) pulses, as described above with respect to FIGS. 1 and 3C. The SP pulses have a repetition frequency. The pulsed plasma process generates a plasma.

In step 804, a substrate is etched with the plasma, as described above with respect to FIG. 3. In step 806, while etching the substrate, the repetition frequency of the SP pulses is continuously changed, as described above with respect to FIGS. 2 and 3C.

FIG. 9 illustrates a process flow chart diagram of a method 900 for processing a substrate, in accordance with some embodiments. In step 902, a substrate is provided onto a substrate holder in a process chamber, as described above with respect to FIG. 1.

In step 904, an opening is etched into the substrate with a pulsed plasma process, as described above with respect to FIG. 3C. In step 906 of the pulsed plasma process, a plasma is generated with source power pulses, as described above with respect to FIGS. 1 and 3C. The plasma comprises carbon, fluorine, oxygen, nitrogen, hydrogen, or argon. In step 908 of the pulsed plasma process, while generating the plasma, a repetition frequency of the source power pulses is ramped down, as described above with respect to FIGS. 2 and 3C.

In step 910, the opening is filled with a conductive material, as described above with respect to FIG. 3D.

Example embodiments of the disclosure are summarized here. Other embodiments can also be understood from the entirety of the specification as well as the claims filed herein.

Example 1. A method for a plasma process, the method including: generating plasma within a process chamber with source power (SP) pulses, the SP pulses having a repetition frequency; and adjusting a neutral flux within the process chamber by changing the repetition frequency of the SP pulses.

Example 2. The method of example 1, where changing the repetition frequency of the SP pulses includes a ramping up from a first frequency to a second frequency, the second frequency being higher than the first frequency.

Example 3. The method of example 2, where the ramping occurs over a time period in a range of 10 microseconds to 1 second.

Example 4. The method of one of examples 1 to 3, where changing the repetition frequency of the SP pulses includes a ramping down from a third frequency to a fourth frequency, the fourth frequency being lower than the third frequency.

Example 5. The method of one of examples 1 to 4, where the third frequency is 2 kHz or greater and the fourth frequency is 1 kHz or less.

Example 6. The method of one of examples 1 to 5, where the plasma is generated from a precursor gas including argon, tetrafluoromethane, oxygen, hexafluorobutadiene, octafluorocyclobutane, nitrogen, hydrogen, or hydrogen bromide.

Example 7. The method of one of examples 1 to 3, where changing the repetition frequency of the SP pulses is a monotonic increase.

Example 8. The method of example 1, where changing the repetition frequency of the SP pulses is a monotonic decrease.

Example 9. The method of one of examples 1 to 8, where changing the repetition frequency of the SP pulses is continuous.

Example 10. A method for an etch process, the method including: starting a pulsed plasma process with source power (SP) pulses, the SP pulses having a repetition frequency, the pulsed plasma process generating a plasma; etching a substrate with the plasma; and while etching the substrate, continuously changing the repetition frequency of the SP pulses.

Example 11. The method of example 10, where continuously changing the repetition frequency of the SP pulses includes ramping down the repetition frequency monotonically.

Example 12. The method of example 10, where continuously changing the repetition frequency of the SP pulses includes ramping up the repetition frequency monotonically.

Example 13. The method of one of examples 10 to 12, where the plasma is generated from a precursor gas including argon, tetrafluoromethane, oxygen, hexafluorobutadiene, octafluorocyclobutane, nitrogen, hydrogen, or hydrogen bromide.

Example 14. The method of one of examples 10 to 13, where continuously changing the repetition frequency of the SP pulses includes changing an F/C neutral flux ratio of the plasma.

Example 15. A method for processing a substrate, the method including: providing a substrate onto a substrate holder in a process chamber; etching an opening into the substrate with a pulsed plasma process, the pulsed plasma process including: generating a plasma with source power pulses, the plasma including carbon, fluorine, oxygen, nitrogen, hydrogen, or argon; and while generating the plasma, ramping down a repetition frequency of the source power pulses; and filling the opening with a conductive material.

Example 16. The method of example 15, where the opening is a high aspect ratio opening.

Example 17. The method of one of examples 15 or 16, where filling the opening with a conductive material forms a through substrate via.

Example 18. The method of one of examples 15 to 17, where the opening is etched into the substrate to a depth in a range of 10 μm to 100 μm.

Example 19. The method of one of examples 15 to 18, where the ramping down of the repetition frequency of the source power pulses includes monotonically changing an instantaneous frequency of the source power pulses.

Example 20. The method of one of examples 15 to 19, where the ramping down of the repetition frequency of the source power pulses includes continuously changing an instantaneous frequency of the source power pulses.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for a plasma process, the method comprising:
generating plasma within a process chamber with source power (SP) pulses, the SP pulses having a repetition frequency; and
adjusting a neutral flux within the process chamber by changing the repetition frequency of the SP pulses.

2. The method of claim 1, wherein changing the repetition frequency of the SP pulses comprises a ramping up from a first frequency to a second frequency, the second frequency being higher than the first frequency.

3. The method of claim 2, wherein the ramping occurs over a time period in a range of 10 microseconds to 1 second.

4. The method of claim 1, wherein changing the repetition frequency of the SP pulses comprises a ramping down from a third frequency to a fourth frequency, the fourth frequency being lower than the third frequency.

5. The method of claim 4, wherein the third frequency is 2 kHz or greater and the fourth frequency is 1 kHz or less.

6. The method of claim 1, wherein the plasma is generated from a precursor gas comprising argon, tetrafluoromethane, oxygen, hexafluorobutadiene, octafluorocyclobutane, nitrogen, hydrogen, or hydrogen bromide.

7. The method of claim 1, wherein changing the repetition frequency of the SP pulses is a monotonic increase.

8. The method of claim 1, wherein changing the repetition frequency of the SP pulses is a monotonic decrease.

9. The method of claim 1, wherein changing the repetition frequency of the SP pulses is continuous.

10. A method for an etch process, the method comprising:
starting a pulsed plasma process with source power (SP) pulses, the SP pulses having a repetition frequency, the pulsed plasma process generating a plasma;
etching a substrate with the plasma; and
while etching the substrate, continuously changing the repetition frequency of the SP pulses.

11. The method of claim 10, wherein continuously changing the repetition frequency of the SP pulses comprises ramping down the repetition frequency monotonically.

12. The method of claim 10, wherein continuously changing the repetition frequency of the SP pulses comprises ramping up the repetition frequency monotonically.

13. The method of claim 10, wherein the plasma is generated from a precursor gas comprising argon, tetrafluoromethane, oxygen, hexafluorobutadiene, octafluorocyclobutane, nitrogen, hydrogen, or hydrogen bromide.

14. The method of claim 10, wherein continuously changing the repetition frequency of the SP pulses comprises changing an F/C neutral flux ratio of the plasma.

15. A method for processing a substrate, the method comprising:
providing a substrate onto a substrate holder in a process chamber;
etching an opening into the substrate with a pulsed plasma process, the pulsed plasma process comprising:
generating a plasma with source power pulses, the plasma comprising carbon, fluorine, oxygen, nitrogen, hydrogen, or argon; and
while generating the plasma, ramping down a repetition frequency of the source power pulses; and
filling the opening with a conductive material.

16. The method of claim 15, wherein the opening is a high aspect ratio opening.

17. The method of claim 15, wherein filling the opening with the conductive material forms a through substrate via.

18. The method of claim 15, wherein the opening is etched into the substrate to a depth in a range of 10 μm to 100 μm.

19. The method of claim 15, wherein the ramping down of the repetition frequency of the source power pulses comprises monotonically changing an instantaneous frequency of the source power pulses.

20. The method of claim 15, wherein the ramping down of the repetition frequency of the source power pulses comprises continuously changing an instantaneous frequency of the source power pulses.
